(19) United States
(12) Patent Application Publication
(10) Pub. No.: US 2026/0169905 A1
(43) Pub. Date: Jun. 18, 2026

(54) COMPENSATION SCHEME FOR ANALOG IN-MEMORY MATRIX MULTIPLICATION

(71) Applicant: International Business Machines Corporation, Armonk, NY (US)

(72) Inventors: Abhairaj Singh, Adliswil (CH); Pritish Narayanan, San Jose, CA (US); Manuel Le Gallo-Bourdeau, Horgen (CH); Abu Sebastian, Adliswil (CH)

(21) Appl. No.: 18/978,822

(22) Filed: Dec. 12, 2024

(51) Int. Cl. G06F 12/02; G06F 17/16; H03M 1/12

(52) U.S. Cl. CPC G06F 12/0207; G06F 17/16; H03M 1/1215

(57) ABSTRACT

Computing devices and methods are provided for executing analog in-memory computing for matrix vector multiplication. Values of a matrix are mapped to conductance values of a memory crossbar array. Analog voltage values of an activation vector are inputted to the memory cells of the memory crossbar array. Non-linear output values are generated, via the memory cells, from the analog voltage values and the mapped conductance values. Time varying voltage values are also generated via the memory cells of the memory crossbar array. The time varying voltage values are used to linearize the analog non-linear output values into analog linear output values and convert the analog linear output values to digital linear output values to compensate for potential inaccuracies of the non-linear output values.

### BACKGROUND

The present application relates to devices and methods for in-memory computing of matrix-vector multiplication (MVM) operations, and more particularly, to devices and methods for analog in-memory computing (AIMC) of MVM operations using voltage to time converter (VTC) based analog to digital converters (ADCs).

In-memory computing is an emerging architecture in which both data storage and data computing are performed in a memory network of a computing device. In-memory computing is used to improve the overall performance of a computing device executing an application by processing a large amount of data stored within a memory network without having to move the data between a processor and memory. In-memory computing is used in a wide range of applications such as, for example, signal processing, machine learning, deep learning, and computer graphics.

### SUMMARY

In some embodiments, a computing device is provided which includes a memory crossbar array, control logic circuitry and a plurality of analog to digital converters. The memory crossbar array includes a plurality of memory cells each configured to store a value of a matrix to a conductance. The memory crossbar array also includes control logic circuitry configured to execute, via the plurality of memory cells, analog in-memory computing for matrix vector multiplication. The control logic circuitry is configured to execute the analog in-memory computing for matrix vector multiplication by controlling the plurality of memory cells to generate non-linear output values from the stored values of the matrix and analog input values of a vector. The control logic circuitry is also configured to execute the analog in-memory computing for matrix vector multiplication by generating, time varying voltage values. The plurality of analog to digital converters are configured to use the time varying voltage values to linearize the non-linear output values into analog linear output values and convert the analog linear output values to digital linear output values.

In some embodiments, a computer-implemented method is provided which includes mapping values of a matrix to conductance values of a memory crossbar array. The method includes inputting, to the memory cells of the memory crossbar array, analog voltage values of an activation vector. The method also includes generating non-linear output values from the analog voltage values and the mapped conductance values. The method also includes generating, via the memory cells of the memory crossbar array, time varying voltage values. The method further includes using the time varying voltage values to linearize the analog non-linear output values into analog linear output value and convert the analog linear output values to digital linear output values.

In some embodiments, a computer program product is provided which includes one or more computer-readable storage media and program instructions stored on the one or more computer-readable storage media to perform operations. The operations include mapping values of a matrix to conductance values of a memory crossbar array. The operations also include inputting, to the memory cells of the memory crossbar array, analog voltage values of an activation vector. The operations also include generating non-linear output values from the analog voltage values and the mapped conductance values. The operations also include generating, via the memory cells of the memory crossbar array, time varying voltage values. The operations further include using the time varying voltage values to linearize the analog non-linear output values into analog linear output value and converting the analog linear output values to digital linear output values.

In some embodiments, a computing device is provided which includes a memory crossbar array, control logic circuitry and a plurality of analog to digital converters. The memory crossbar array includes a plurality of columns of memory cells. Each memory cell is configured to store a value of a matrix to a conductance. The plurality of columns of memory cells includes groups of columns of memory cells. Each column of memory cells in a group of memory cells is configured to generate a non-linear output value from stored values of the matrix and analog input values of a vector. The dummy columns of memory cells are interleaved between, and separate from, the groups of columns of memory cells. Each dummy column is configured to generate a time varying voltage value for a portion of the groups of columns of memory cells adjacent to a corresponding dummy column. The control logic circuitry is configured to execute, via the plurality of columns of memory cells, analog in-memory computing for matrix vector multiplication by controlling each column of memory cells to generate the non-linear output value from the stored values of the matrix and the analog input values of the vector. The control logic circuitry is also configured to execute the analog in-memory computing for matrix vector multiplication by controlling each column of memory cells to generate, the time varying voltage value for the portion of the groups of columns of memory cells adjacent to the corresponding dummy column. The plurality of analog to digital converters are configured to use the time varying voltage values to linearize the non-linear output values into analog linear output values and convert the analog linear output values to digital linear output values.

In some embodiments, a method is provided which includes configuring a memory crossbar array, including a plurality of columns of memory cells, to store a value of a matrix to a conductance in each memory cell. The method also includes, for the plurality of columns of memory cells, configuring each column of memory cells in a group of memory cells to generate a non-linear output value from the stored values of the matrix and analog input values of a vector. The method also includes configuring each of a plurality of dummy columns of memory cells, interleaved between and separate from the groups of columns of memory cells, to generate a time varying voltage value for a portion of the groups of columns of memory cells adjacent to a corresponding dummy column. The method also includes executing, via the plurality of columns of memory cells, analog in-memory computing for matrix vector multiplication by controlling each column of memory cells to generate the non-linear output value from the stored values of the matrix and the analog input values of the vector. The method also includes executing, the analog in-memory computing for the matrix vector multiplication by controlling each dummy column to generate, the time varying voltage value for the portion of the groups of columns of memory cells adjacent to the corresponding dummy column. The method further includes using the time varying voltage values to linearize the analog non-linear output values into analog linear output values and convert the analog linear output values to digital linear output values.

### BRIEF DESCRIPTION OF THE DRAWINGS

FIG. 1 shows an example computing environment in which embodiments of the present disclosure can be implemented.

FIG. 2 is a diagram illustrating example AIMC computing components used to execute an MVM operation for a matrix and a vector according to an embodiment of the present disclosure.

FIG. 3 is a flow diagram illustrating an exemplary computer implemented method of executing MVM operations using AIMC in accordance with embodiments of the present disclosure.

FIG. 4 shows a timing diagram illustrating an implementation of a time varying voltage dummy ramp signal for three non-linear analog values according to embodiments of the present disclosure.

FIG. 5 shows a timing diagram further illustrating the implementation of the time varying voltage dummy ramp signal shown in FIG. 4.

FIG. 6 illustrates example circuitry configured to compensate for the potentially inaccurate outputs of the MVM operations using a dummy column of memory cells according to an embodiment of the present disclosure.

FIG. 7 illustrates example circuitry configured to compensate for the potentially inaccurate outputs of the MVM operations using existing memory cell columns as reference columns according to an embodiment of the present disclosure.

FIG. 8 is a diagram illustrating analog to digital conversion in each cycle of a bit-serial input encoding and accumulation of partial results on a counter, according to an embodiment of the present disclosure.

FIG. 9 is a diagram illustrating a multi-ramp scheme for processing the analog voltage values before the analog voltage values are converted into digital form according to an embodiment of the present disclosure.

FIG. 10 is a diagram illustrating a single-ramp scheme for processing the analog voltage values before the analog voltage values are converted into digital form according to an embodiment of the present disclosure.

### DETAILED DESCRIPTION

In some embodiments, a computing device is provided which comprises a memory crossbar array and a plurality of analog to digital converters. The memory crossbar array comprises a plurality of memory cells each configured to store a value of a matrix to a conductance. The memory crossbar array also comprises control logic circuitry configured to execute, via the plurality of memory cells, analog in-memory computing for matrix vector multiplication. The control logic circuitry is configured to execute the analog in-memory computing for matrix vector multiplication by controlling the plurality of memory cells to generate non-linear output values from the stored values of the matrix and analog input values of a vector. The control logic circuitry is also configured to execute the analog in-memory computing for matrix vector multiplication by generating, time varying voltage values. The plurality of analog to digital converters are configured to use the time varying voltage values to linearize the non-linear output values into analog linear output values and convert the analog linear output values to digital linear output values.

In this way, non-linear output values from the stored values of the matrix and analog input values of a vector generated via the memory cells are further updated using the time varying voltage values. Using the time varying voltage values compensate for potential inaccuracies of the non-linear output values affected by factors such as noise in hardware, voltage drop and/or capacitor discharge.

One or more of the following features can be separable or optional from each other.

In an embodiment, the memory crossbar array comprises a plurality of columns of memory cells and a dummy column of memory cells. Each column of memory cells is configured to generate a non-linear output value from the stored values of the matrix and the analog input values of the vector. The dummy column of memory cells is separate from, and adjacent to, groups of the plurality of columns of memory cells. The dummy column is configured to generate the time varying voltage values for a portion of the groups of the plurality of columns of memory cells adjacent to the dummy column.

In this way, a memory crossbar array can be used to produce both the time varying voltage values and the output values and using the dummy columns of memory cells, separate from the groups of columns of memory cells, provides for the generating of the time varying voltage values by the dummy columns while allowing each of the groups of columns of memory cells to generate the non-linear output values from stored values of the matrix and analog input values of a vector.

In another embodiment, the memory crossbar array comprises a plurality of columns of memory cells. Each column of memory cells is configured to generate a non-linear output value from the stored values of the matrix and the analog input values of the vector, A column of memory cells, of the plurality of columns of memory cells, is configured to generate the time varying voltage values for the plurality of columns of memory cells.

In this way, using existing columns of memory cells to generate the time varying voltage values allows the memory crossbar array to produce both the time varying voltage values and the non-linear output values without additional memory area.

According to one aspect of an embodiment, the column of memory cells is a column of memory cells which includes a maximum conductance of the plurality of columns of memory cells. In this way, the time varying voltage values can be used for all ranges of output values generated from stored values of the matrix and analog input values of a vector.

In one embodiment, the control logic circuitry is configured to control the plurality of analog to digital converters to use the time varying voltage values to linearize the analog non-linear output values into analog linear output values and convert the analog linear output values to digital linear output values.

In this way, linearization is performed within digital converters of the memory crossbar array.

In another embodiment, the analog to digital converters comprise additional control logic circuitry configured to use the time varying voltage values to linearize the analog non-linear output values into analog linear output values and convert the analog linear output values to digital linear output values.

In this way, a separate modular control logic circuity can be used for linearizing and converting the output values using the time varying voltage values.

In an aspect of an embodiment, the non-linear output values are non-linear voltage values. In this way, non-linear voltage values are processed as output values.

In another aspect of an embodiment, the non-linear output values are non-linear current values. In this way, non-linear current values are processes as output values.

According to one embodiment, a time varying voltage value is used in each of a plurality of input activation cycles of an analog non-linear output value to convert the analog non-linear output value to an intermediate linear output value and combine each intermediate linear output value to convert the analog non-linear output value to a digital linear output value. This may allow for accommodating multi-bit inputs.

According to another embodiment, a single time varying voltage value is used for a plurality of input activation cycles of an analog non-linear output value to convert the analog non-linear output value to a digital linear output value. This allows for using a varying voltage value one time for converting the analog non-linear output values.

In some embodiments, a computer-implemented method is provided which comprises mapping values of a matrix to conductance values of a memory crossbar array. The method comprises inputting, to the memory cells of the memory crossbar array, analog voltage values of an activation vector. The method also comprises generating non-linear output values from the analog voltage values and the mapped conductance values. The method also comprises generating, via the memory cells of the memory crossbar array, time varying voltage values. The method further comprises using the time varying voltage values to linearize the analog non-linear output values into analog linear output value and convert the analog linear output values to digital linear output values. In this way, non-linear output values from the stored values of the matrix and analog input values of a vector generated via the memory cells are further updated using the time varying voltage values. Using the time varying voltage values compensate for potential inaccuracies of the non-linear output values affected by factors such as noise in hardware, voltage drop and/or capacitor discharge.

One or more of the following features can be separable or optional from each other.

According to an embodiment, the method further comprises generating the time varying voltage values via a dummy column of memory cells, which is separate from columns of memory cells used to generate the non-linear output values.

In this way, a memory crossbar array can be used to produce both the time varying voltage values and the output values and using the dummy columns of memory cells, separate from the groups of columns of memory cells, provides for the generating of the time varying voltage values by the dummy columns while allowing each of the groups of columns of memory cells to generate the non-linear output values from stored values of the matrix and analog input values of a vector..

According to another embodiment, the method further comprises generating the time varying voltage values via a reference column of memory cells which is part of a group of the memory cells used to generate the non-linear output values.

In this way, using an existing column of memory cells in the memory crossbar array to generate time varying voltage values allows the memory crossbar array to produce both the time varying voltage values and the non-linear output values without additional memory area.

In one aspect of an embodiment, the non-linear output values are non-linear voltage values. Non-linear voltage values may be processed as output values.

In another aspect of an embodiment, the non-linear output values are non-linear

current values. Non-linear current values may be processes as output values.

According to an embodiment, bits corresponding to the analog voltage values of the activation vector are input serially to the memory cells in each clock cycle and the method further comprises converting, in each clock cycle, the analog non-linear output voltage value and accumulating, for each clock cycle via a counter, a partial value of the analog non-linear output voltage value while accounting for a significance of a corresponding bit of analog non-linear output voltage value. This may allow for accommodating multi-bit inputs.

According to another embodiment, the method further comprises using a time varying voltage value in each of a plurality of input activation cycles of an analog non-linear output value to convert the analog non-linear output value to an intermediate linear output value and combining each intermediate linear output value to convert the analog non-linear output value to a digital linear output value. This may allow for accommodating multi-bit inputs using intermediary processing.

In another embodiment, the method further comprises using a single time varying voltage value for a plurality of input activation cycles of an analog non-linear output value to convert the analog non-linear output value to a digital linear output value. This allows for using one time varying voltage value for converting the analog non-linear output values.

In some embodiments, a computer program product is provided which comprises one or more computer-readable storage media and program instructions stored on the one or more computer-readable storage media to perform operations. The operations comprise mapping values of a matrix to conductance values of a memory crossbar array. The operations also comprise inputting, to the memory cells of the memory crossbar array, analog voltage values of an activation vector. The operations also comprise generating non-linear output values from the analog voltage values and the mapped conductance values. The operations also comprise generating, via the memory cells of the memory crossbar array, time varying voltage values. The operations further comprise using the time varying voltage values to linearize the analog non-linear output values into analog linear output value and converting the analog linear output values to digital linear output values.

In this way, non-linear output values from the stored values of the matrix and analog input values of a vector generated via the memory cells are further updated using the time varying voltage values. Using the time varying voltage values compensate for potential inaccuracies of the non-linear output values affected by factors such as noise in hardware, voltage drop and/or capacitor discharge.

One or more of the following features can be separable or optional from each other.

In an embodiment, the operations further comprise generating the time varying voltage values via a dummy column of memory cells, which is separate from columns of memory cells used to generate the non-linear output values.

In this way, a memory crossbar array can be used to produce both the time varying voltage values and the output values and using the dummy columns of memory cells, separate from the groups of columns of memory cells, provides for the generating of the time varying voltage values by the dummy columns while allowing each of the groups of columns of memory cells to generate the non-linear output values from stored values of the matrix and analog input values of a vector..

In an embodiment, the operations further comprise generating the time varying voltage values via a reference column of memory cells which is part of a group of the memory cells used to generate the non-linear output values. In this way, a column of memory cells in the memory crossbar array can generate time varying voltage values.

In an aspect of an embodiment, the non-linear output values are non-linear voltage values. Non-linear voltage values may be processed as output values.

In another aspect of an embodiment, the non-linear output values are non-linear current values. Non-linear current values may be processes as output values.

In some embodiments, a computing device is provided which comprises a memory crossbar array, control logic circuitry and a plurality of analog to digital converters. The memory crossbar array comprises a plurality of columns of memory cells. Each memory cell is configured to store a value of a matrix to a conductance. The plurality of columns of memory cells comprises groups of columns of memory cells. Each column of memory cells in a group of memory cells is configured to generate a non-linear output value from stored values of the matrix and analog input values of a vector. The plurality of columns of memory cells also comprises dummy columns of memory cells, interleaved between and separate from the groups of columns of memory cells. Each dummy column is configured to generate a time varying voltage value for a portion of each adjacent group of columns of memory cells. The control logic circuitry is configured to execute, via the plurality of columns of memory cells, analog in-memory computing for matrix vector multiplication by controlling each column of memory cells to generate the non-linear output value from the stored values of the matrix and the analog input values of the vector. The control logic circuitry is also configured to execute the analog in-memory computing for matrix vector multiplication by controlling each column of memory cells to generate a time varying voltage value. The plurality of analog to digital converters are configured to use the time varying voltage values to linearize the analog non-linear output value into an analog linear output values and convert the analog linear output value to a digital linear output value.

In this way, non-linear output values from the stored values of the matrix and analog input values of a vector generated via the memory cells are further updated using the time varying voltage values. Using the time varying voltage values compensates for potential inaccuracies of the non-linear output values affected by factors such as noise in hardware, voltage drop and/or capacitor discharge. A dummy column of memory cells generates time varying voltage values separate from generating of output values from stored values of the matrix and analog input values of a vector. Using dummy columns of memory cells, separate from the groups of columns of memory cells, provides for the generating of the time varying voltage values by the dummy columns while allowing each of the groups of columns of memory cells to generate the non-linear output values from stored values of the matrix and analog input values of a vector.

In some embodiments, a method is provided which comprises configuring a memory crossbar array, including a plurality of columns of memory cells, to store a value of a matrix to a conductance in each memory cell. The method also comprises, for the plurality of columns of memory cells, configuring each column of memory cells in a group of memory cells to generate a non-linear output value from the stored values of the matrix and analog input values of a vector. The method also comprises configuring each of a plurality of dummy columns of memory cells, interleaved between and separate from the groups of columns of memory cells, to generate a time varying voltage value for a portion of the groups of columns of memory cells adjacent to a corresponding dummy column. The method also comprises executing, via the plurality of columns of memory cells, analog in-memory computing for matrix vector multiplication by controlling each column of memory cells to generate the non-linear output value from the stored values of the matrix and the analog input values of the vector. The method also comprises executing, the analog in-memory computing for the matrix vector multiplication by controlling each dummy column to generate, the time varying voltage value for the portion of the groups of columns of memory cells adjacent to the corresponding dummy column. The method further comprises using the time varying voltage values to linearize the analog non-linear output values into analog linear output values and convert the analog linear output values to digital linear output value.

In this way, non-linear output values from the stored values of the matrix and analog input values of a vector generated via the memory cells are further updated using the time varying voltage values. Using the time varying voltage values compensate for potential inaccuracies of the non-linear output values affected by factors such as noise in hardware, voltage drop and/or capacitor discharge. A dummy column of memory cells generates time varying voltage values separate from generating of output values from stored values of the matrix and analog input values of a vector. A memory crossbar array can be used to produce both the time varying voltage values and the output values. Using the dummy columns of memory cells, separate from the groups of columns of memory cells, provides for the generating of the time varying voltage values by the dummy columns while allowing each of the groups of columns of memory cells to generate the non-linear output values from stored values of the matrix and analog input values of a vector

The method can also be computer implemented.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

In-memory computing is an emerging architecture in which both data storage and data computing are performed in a memory network of a computing device. In-memory computing is used to improve the overall performance of a computing device executing an application by processing a large amount of data stored within a memory network without having to move the data between a processor and memory.

MVM is a mathematical operation that produces a vector from a matrix and a vector. MVM is a key compute primitive used in a wide range of applications (e.g., machine learning applications, computer graphics applications, artificial intelligence (AI) applications, systems of linear equations and computational mathematics). For example, in-memory computing is used to accelerate MVM operations (e.g., operations executed during deep neural network (DNN) inference and training for machine learning applications).

In-memory computing can be executed as both AIMC and digital in-memory computing (DIMC). AIMC uses analog properties of the resistance-based memory for both storage and computation and processes data in a highly parallel manner. However, while AIMC executes MVM operations more efficiently (i.e., uses less power) than DIMC, the accuracy of the analog outputs (e.g., analog voltage outputs or analog current outputs) of the MVM operations is compromised when using AIMC due to intrinsic circuit noise (e.g., noise associated with the memory cells) and voltage (IR) drop from resistance in the wires through which the analog signals are transmitted. Because the wires are resistive, the amount of voltage (IR) drop across the wires varies depending on the analog inputs. These variations cannot be detected, resulting in potentially inaccurate analog outputs (e.g., non-ideal analog voltage outputs or non-ideal analog current outputs) for the MVM operations. In addition, the execution of the MVM operations is more efficient when more memory cells are used to execute the MVM operations. However, increasing the number of memory cells and wires to execute the MVM operations produces more current (I), resulting in larger variations of the voltage (IR) drop and a greater potential for inaccurate analog outputs of the MVM operations. Further, exponential capacitor discharge (e.g., from current sinking memory devices) can also contribute to results in potentially inaccurate analog outputs.

Features of the present disclosure perform efficient (e.g., area efficient and energy efficient) AIMC MVM operations and compensate for potential inaccuracies of the analog outputs due to noise, voltage (IR) drop and capacitor discharge to improve the accuracy of the outputs. Features of the present disclosure utilize the energy efficiency advantages associated with AIMC MVM operations while reducing the potential inaccuracies of the outputs associated with conventional AIMC MVM techniques. Features of the present disclosure compensate for the potentially inaccurate analog outputs by generating time varying voltages (e.g., dummy signals). Features of the present disclosure also perform the AIMC MVM operations without crossbar section compensation, regulators, or header-footer devices in the ring oscillator (ROSC).

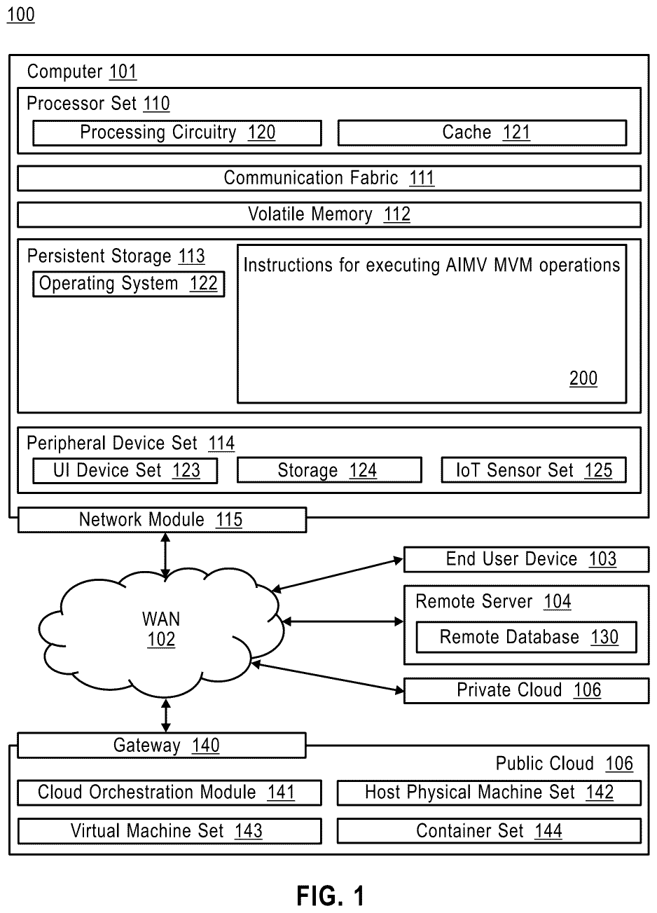

FIG. 1 shows a computing environment 100 in which embodiments of the present disclosure can be implemented. Computing environment 100 contains an example of an environment for the execution of at least some of the computer code involved in performing the inventive methods, such as instructions 200 for executing AIMC MVM operations to execute an application (e.g., a machine learning application, a deep learning application, a computer graphics application, or other application). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 Is the Signal Conduction Path That Allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 Is the Collection of Computer Software, Hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 012 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES (not Separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

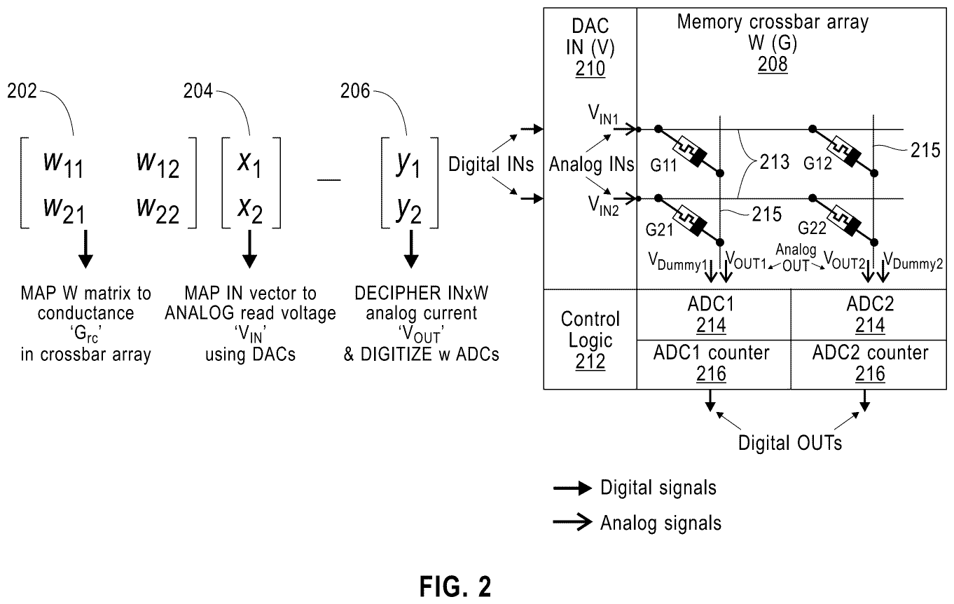

FIG. 2 is a diagram illustrating example AIMC computing components used to execute an MVM operation for a matrix 202 and a vector 204 according to an embodiment of the present disclosure. For simplification purposes, a single MVM operation is shown in FIG. 2. During operation (e.g., execution of a machine learning application), features of the present disclosure are implemented to execute many MVM operations.

The matrix 202 is a 2×2 matrix which includes 2 columns and 2 rows of data (e.g., weights (w) in this example), represented as w₁₁, w₁₂, w₂₁ and w₂₂. The number of columns and rows of the matrix 202 is merely an example. Features of the present disclosure can be implemented for matrices having any number of columns and rows. In addition, vector 204 includes 2 values represented as x₁ and x₂. Features of the present disclosure can be used to perform MVM operations for vectors having any number of values.

The AIMC computing components include memory crossbar array 208, a digital to analog converter (DAC) 210, control logic 212, analog to digital converters (ADCs) 214 and ADC counters 216.

The memory crossbar array 208 shown in FIG. 2 represents a portion of a larger memory crossbar array. The memory crossbar array 208 is for example, part of volatile memory 112 in FIG. 1. Alternatively, the memory crossbar array 208 is separate from the volatile memory 112 (e.g., includes circuitry separate from the volatile memory 112). For simplification purposes, the memory crossbar array 208 includes 2 rows and 2 columns of memory cells represented as G₁₁, G₁₂, G₂₁ and G₂₂. Features of the present disclosure can execute MVM operations using memory crossbar arrays having any number of rows and columns of memory cells. Each memory cell is an analog storage device configured to store an analog value representing a number of bits of data converted into the analog value) into a conductance G (e.g., a conductance ranging from 0-10). The memory crossbar array 208 also includes wires 213 (e.g., also known as bit lines (BLs) and wires 215 (also known as word lines (WLs) configured to transmit analog signals within the memory crossbar array 208.

Control logic 212 is hardware logic circuitry (e.g., logic gates, combinational circuits) which is configured to perform various functions to execute AIMC MVM operations as described herein. For example, as described in more detail below, control logic 212 is configured to generate, via memory cells of the memory crossbar array 208, time varying voltage values (as described in more detail below) which are also output from the memory crossbar array to the ADCs 214 to compensate for inaccurate AIMC MVM outputs.

The MVM operation includes multiplying the matrix 202 by the activation vector 204, having data represented as voltage values x₁ as x₂ to produce an output 206 of the MVM operation, having data represented as y₁ and y₂. The values (e.g., weight values w₁₁, w₁₂, w₂₁ and w₂₂) of matrix 202 are mapped to memory cells (i.e., mapped to a conductance value G of each memory cell) of memory crossbar array 208. For example, weight value w₁₁ of matrix 202 is mapped to a conductance value of memory cell G₁₁, weight value w₁₂ of matrix 202 is mapped to a conductance value of memory cell G₁₂, weight value w₂₁ of matrix 202 is mapped to a conductance value of memory cell G₂₁ and weight value w₂₂ of matrix 202 is mapped to a conductance value of memory cell G₂₂.

The data (x₁ as x₂) of the activation vector 204 are input as digital data, converted by digital to analog converters (DACs) 210 and input into the memory crossbar array 208. For example, the converted analog voltage corresponding to data x₁ of the activation vector 204 is input into the memory crossbar array 208 as analog read voltage V_{IN1} and the converted analog voltage corresponding to data x₂ of the activation vector 204 is input into the memory crossbar array 208 as analog read voltage V_{IN2}.

The analog read voltage V_{IN1} and the analog read voltage V_{IN2} are transmitted, via wires 213 (the horizontal wires in FIG, 2) of the memory crossbar array 208. Non-linear MVM output voltage values V_{OUT1} and V_{OUT2} are then generated, via the memory cells G₁₁, G₁₂, G₂₁ and G₂₂ of the memory crossbar array 208, from the analog voltage values V_{IN1} and V_{IN2} and the mapped conductance values (e.g., weights w₁₁, w₁₂, w₂₁ and w₂₂) of the matrix 202. Alternatively, the non-linear MVM output values are non-linear current values. The analog non-linear output voltage values V_{OUT1} and V_{OUT2} are then sent along wires 215 (e.g., the vertical wires in FIG, 2) to ADCs 214 (e.g., ADC1 and ADC2 in FIG. 2) to the ADCs 114.

In addition, the control logic is also configured to generate time varying voltage values (as described in more detail below) which are also output from the memory crossbar array to the ADCs 214. The time varying voltage values compensate for potentially inaccurate analog non-linear output values during the A/D conversion by the ADCs because the time the varying voltage values are subject to the same intrinsic circuit noise, voltage (IR) drop and capacitor discharge (contributing to the potentially inaccurate outputs) of each generated analog non-linear output value.

The analog voltage values V_{OUT1} and V_{OUT2} are converted by ADCs 214 and provided as digital output data (i.e., digital OUTs) to represent the output 206 of the MVM operation. For example, analog output voltage value V_{OUT1} is converted by ADC1 and analog output voltage value V_{OUT2} is converted by ADC2. Each output is also counted by a corresponding counter 216 (e.g., ADC1 counter and ADC2 counter in FIG. 2) to provide an updated count of the number of digital outputs from each ADC 214.

Analog to digital conversion typically dominates the computational efficiency and accuracy of an AIMC device. While the memory core of the AIMC device performs analog-based computing and produces MVM outputs in the analog domain, analog to digital conversion facilitates the conversion of the analog MVM outputs into the digital domain to enable communication between the different components.

The analog to digital conversion by each ADC (e.g., ADC1 and ADC2) typically includes a sensing stage, followed by a conversion stage and then a decision stage. Each stage provides linear I/O characteristics (e.g., linear relationship between an MVM analog output and its corresponding digital ADC output). The sensing stage ensures that a linear value reaches the ADC as an analog input (e.g., V_{MVM} or I_{MVM}) proportionate to an accurate analog MVM value (V_{MVM}). In voltage-to-time conversion based ADCs, the sensing stage includes using VTCs and sample-hold capacitors to provide intermediate analog values to be converted in the conversion stage. During the conversion stage, the intermediate analog values are converted to discrete quantities (e.g., a discrete number of pulses) which are then used in the decision stage. The conversion stage also includes compensation to address any non-linearities. In time-based ADCs, the conversion stage includes a time-to-digital converter (TDC) which receives the time information from the sensing stage and generates pulses (I_{MVM}) or (V_{MVM}). The number of pulses is proportionate to the voltage output (e.g., less pulses results in lowering the bit value output of the voltage and more pulses results in raising the bit value output of the voltage). In the decision stage, the processor counts the number of pulses generated by the TDC as digital outputs and, depending on the topology of the ADC, the processor also counts the number of states of the ring-oscillator.

The analog read voltages (e.g., V_{IN1} and V_{IN2}) are multi-bit values. The bits representing the value of each analog read voltage are sent, one at a time per clock cycle, via wires 213 (e.g., BLs), to the memory cells G₁₁, G₁₂, G₂₁ and G₂₂ and the analog non-linear output voltage values V_{OUT1} and V_{OUT2} are then sent along wires 215, to the ADCs (i.e., ADC1 and ADC2). However, because each bit has a corresponding significance, during the voltage-based sensing stage the charges are shared between equal sized capacitors to implement a scaling factor for the bits of each analog output voltage value V_{OUT1} and V_{OUT2} to accommodate for the different significances. For example, the first bit of an analog output voltage values V_{OUT1} or V_{OUT2} is multiplied by a scaling factor of 2, the second bit is multiplied by a scaling factor of 4, the third bit is multiplied by a scaling factor of 8, and so on. Alternatively, the values can be scaled by reducing the values of each bit. For example, the value of the first bit can be reduced by reducing by a scaling factor of ½, the value of the second bit can be reduced by a scaling factor of ¼, and so on. In this example, a first capacitor that stores the value for the first bit (reduced by a scaling factor of ½) shares its charge (i.e., its unused charge portion) with a second capacitor (joining capacitor) that stores the value for the second bit (reduced by a scaling factor of ¼) so that the second capacitor can use the shared charge of the first capacitor and part of its own charge to store the value for the second bit. The second capacitor shares its charge (i.e., its unused charge portion) with a third capacitor that stores the value for the third bit (reduced by a scaling factor of ⅛) so that the third capacitor can use the shared charge of the second capacitor and part of its own charge to store the value for the third bit, and so on.

Also, for each cycle during the voltage-based sensing stage, the effective conductance of a column of memory cells (e.g., first column including G₁₁ and G₁₂ in FIG. 2 or the second column including G₂₁ and G₂₂ in FIG. 2) is quantified by the amount of discharge that has occurred during a fixed pre-determined time. The amount of discharge is typically quantified using a large capacitance, pre-charging the capacitor before the start of the cycle and keeping it floating. During a read cycle, the current is linear reducing, the voltage is quadratic changing (assuming the resistance R remains constant for the entire range of ΔV). The voltage-based sensing includes a preset phase in which the capacitor is pre-charged, a read cycle phase having a fixed duration in which the capacitor is floating and is discharged by the analog output current, and a result phase producing an output voltage V_{OUT1} or V_{OUT2} which is proportional to the analog output current.

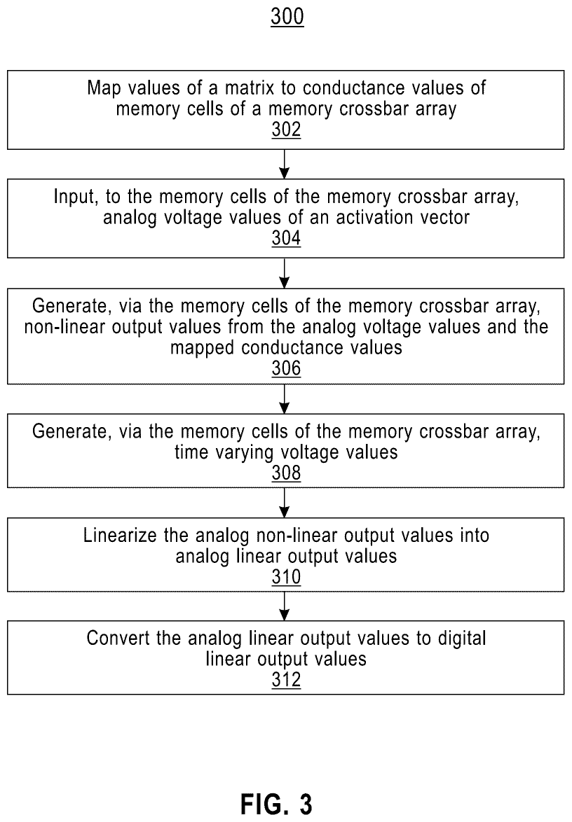

FIG. 3 is a flow diagram illustrating an exemplary computer implemented method 300 of executing MVM operations using AIMC in accordance with embodiments of the present disclosure. Each of the functions described in method 300 are implemented via hardware logic (e.g., control logic 212 shown in FIG. 2 and its associated control signals).

As shown at block 302, the method 300 includes mapping values of a matrix (e.g., matrix 202 shown in FIG. 2) to conductance values of memory cells of a memory crossbar array (e.g., memory cells G₁₁, G₁₂, G₂₁ and G₂₂ of memory crossbar array 208). For example, weight value w₁₁ of matrix 202 is mapped to a conductance value of memory cell G₁₁, weight value w₁₂ of matrix 202 is mapped to a conductance value of memory cell G₁₂, weight value w₂₁ of matrix 202 is mapped to a conductance value of memory cell G₂₁ and weight value w₂₂ of matrix 202 is mapped to a conductance value of memory cell G₂₂.

As shown at block 304, the method 300 includes inputting, to the memory cells of the memory crossbar array, analog voltage values of an activation vector. For example, the data (x₁ as x₂) of the activation vector 204 shown in FIG. 2 are input to, and converted by, DACs 210 to analog voltage values. The analog voltage value corresponding to data x₁ of the activation vector 204 is input into the memory crossbar array 208 as analog read voltage V_{IN1} and the analog voltage corresponding to data x₂ of the activation vector 204 is input into the memory crossbar array 208 as analog read voltage V_{IN2}.

As shown at block 306, the method 300 includes generating, via the memory cells of the memory crossbar array, non-linear output values from the analog voltage values and the mapped conductance values. For example, the non-linear output values are generated by the memory cells G₁₁, G₁₂, G₂₁ and G₂₂ of memory crossbar array 208 from the analog voltage values V_{IN1} and V_{IN2} and the mapped conductance values (e.g., weights w₁₁, w₁₂, w₂₁ and w₂₂) of the matrix 202. The analog non-linear output values (e.g., output voltage values V_{OUT1} and V_{OUT2} in FIG. 2) are then sent along wires 215 (e.g., the vertical wires in FIG, 2) to ADCs 214 (e.g., ADC1 and ADC2 in FIG. 2).

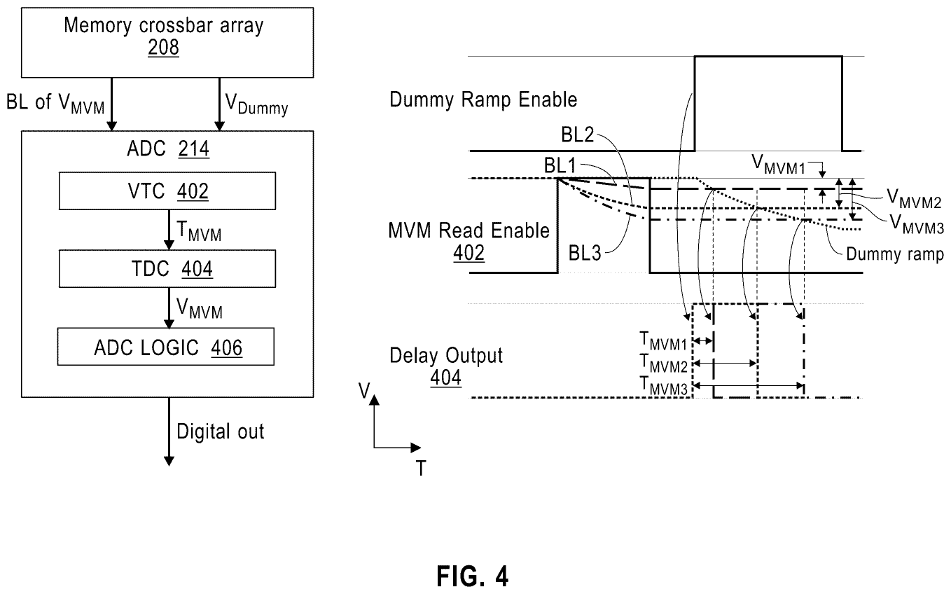

As shown at block 308, the method 300 includes generating, via the memory cells of the memory crossbar array, time varying voltage values (e.g., V_{Dummy} in FIG. 4). The time varying voltage values are subject to the same intrinsic circuit noise, voltage (IR) drop and capacitor discharge (contributing to the potential inaccuracies) of the analog non-linear output values. Accordingly, the time varying voltage values are used to compensate for the potentially inaccurate analog non-linear output values during the analog to digital conversion.

As shown at block 310, the method 300 includes linearizing the analog non-linear output values into analog linear output values. For example, using the time varying voltage values as a reference, the ADCs linearize the analog non-linear output values into analog linear output values.

As shown at block 312, the method 300 includes converting the analog linear output values to digital linear output values. For example, the analog linear output values are converted, by ADCs (e.g., ADCs 214 in FIG. 2) to digital output values (i.e., digital OUTs shown in FIG. 2) to represent the output 206 of the MVM operation. Each digital output value is also counted by a corresponding counter 216 (e.g., ADC1 counter and ADC2 counter in FIG. 2) to provide an updated count of the number of digital outputs from each ADC 214.

Blocks 310-312 of method 300 are now described in further detail.

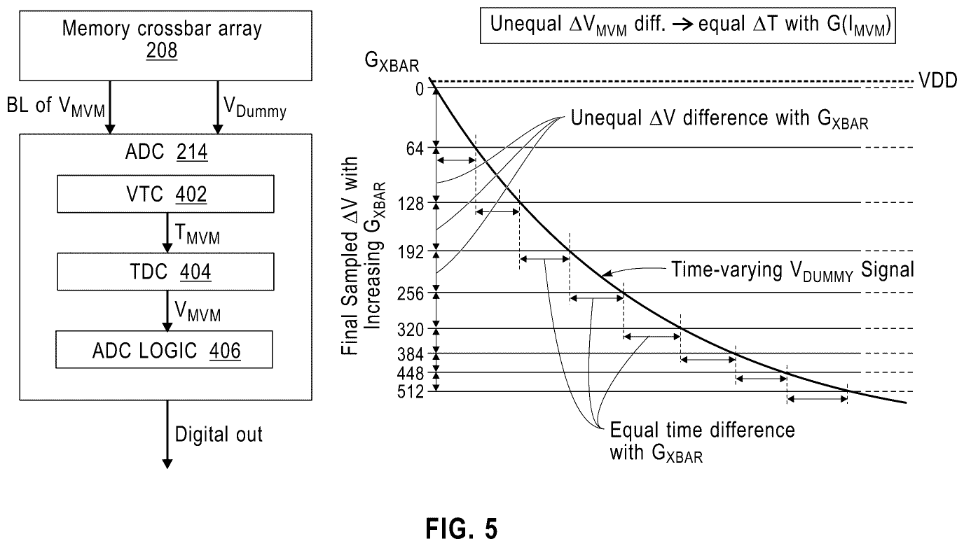

As described above, time varying voltage values (e.g., V_{Dummy} in FIG. 4) are generated via the memory cells of the memory crossbar array to compensate for the potential inaccuracies (i.e., due to the circuit noise, voltage (IR) drop) and capacitor discharge of the analog non-linear output values during analog to digital conversion and improve the accuracy. The time varying voltage values are generated using dummy ramp signals, as described in more detail below with reference to FIGS. 4 and 5.

FIG. 4 shows a timing diagram illustrating an implementation of a time varying voltage dummy ramp signal for three non-linear analog values according to embodiments of the present disclosure.

As shown on the left side of FIG. 4, the ADC 214 receives, during the sensing stage, the time varying voltage dummy ramp signal V_{Dummy} and the non-linear output voltage signal V_{MVM} (e.g., V_{OUT1} or V_{OUT2} shown in FIG. 2), which corresponds to a bit line (BL) of an analog read voltage. The ADC 214 includes voltage to time converter (VTC) 402, time to digital converter (TDC) 406 and ADC control logic 406. The ADC 214 combines the two signals so that, during the conversion stage, the ADC 214 can use V_{Dummy} as a reference to linearize the non-linear output voltage signal V_{MVM} and convert the linearized output voltage signal into a linear digital output.

The right side of FIG. 4 shows a timing diagram illustrating an example of this process for three separate non-linear analog values (each corresponding to a BL of the MVM value). As shown, when each non-linear analog signal BL1, BL2 and BL3 is combined with the non-linear dummy ramp of the linear dummy ramp signal V_{Dummy}, the non-linear analog signals BL1, BL2 and BL3 are converted to linear signals at 402 and then converted to linear digital signals at 404.

FIG. 5 further illustrates the implementation of the time varying voltage dummy ramp signal shown in FIG. 4. The Y axis of the timing diagram in FIG. 5 shows the change in the conductance G (corresponding to the bit significance) of the non-linear output voltage signal V_{MVM} over time.

As shown in FIG. 5, the value of the non-linear analog output voltage signal V_{MVM} increases as the conductance corresponding to the bit significance G_{XBAR} increases. However, the value of the non-linear analog output voltage signal V_{MVM} does not increase proportionately with the conductance corresponding to the bit significance G_{XBAR}. That is, the conductance corresponding to the bit significance G_{XBAR} increases by 64, but the value of the non-linear analog output voltage signal V_{MVM} does not increase by 64 (i.e., the horizontal lines are getting closer together (increasing at a lesser rate) as the conductance corresponding to the bit significance G_{XBAR} increases at a fixed rate of 64). To detect the unequal increase in V_{MVM}, the voltage value of the dummy signal V_{Dummy} is slowed down (i.e., ramped down) over time such that the time intervals between each G_{XBAR} value remain equal (i.e., constant) or close to equal, Accordingly, the output time (i.e., the time intervals between each G_{XBAR}) is linear with respect to a non-linear output voltage.

That is, the dummy ramp signal translates the non-linear relationship (e.g., due to circuit noise, voltage (IR) drop and exponential capacitor discharge) between the potentially inaccurate analog non-linear output values and corresponding accurate MVM output values into a linear related time duration T_{MVM}. The rate of change of the dummy ramp (i.e., the rate of change of the dummy voltage V_{Dummy}) is continuously compared with the sampled input voltage V_{MVM}. The time T_{MVM} is captured from the starting of the ramp to the voltage crossing of this ramp and the sampled V_{MVM} and this time duration is linear to the accurate MVM value. The dummy voltage V_{Dummy} is, for example, calibrated by tuning the RC parasitics of the dummy ramp of the dummy voltage V_{Dummy}. After it is calibrated, the dummy ramp continuously captures the non-linearity of V_{MVM} at any given voltage value to compensate for the potentially inaccurate outputs of the MVM operations.

The compensation for the potentially inaccurate outputs of the MVM operations using the dummy voltage V_{Dummy} can be implemented via various embodiments.

In an embodiment, the compensation for the potentially inaccurate outputs of the MVM operations is implemented by using a dummy column of memory cells in the memory crossbar array 208.

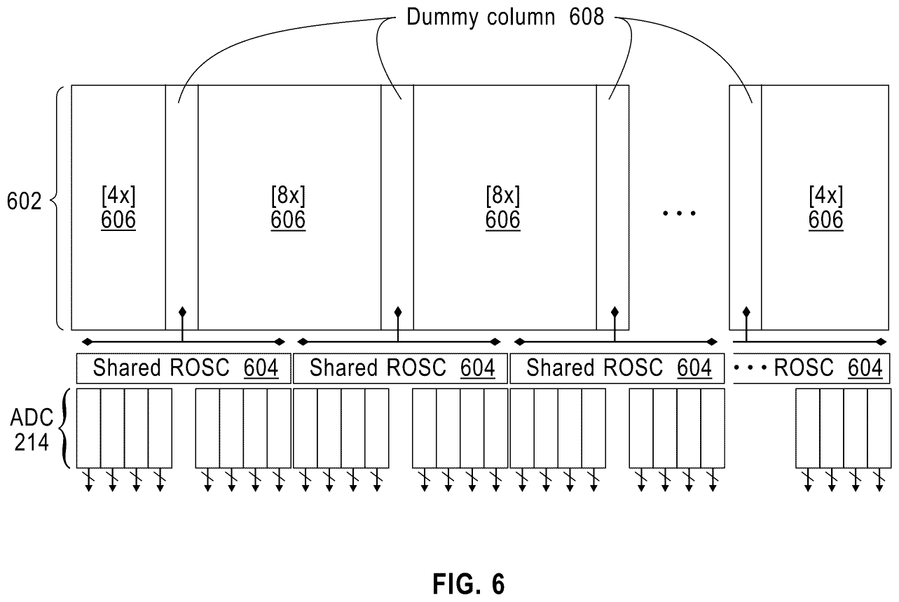

For example, FIG. 6 illustrates example circuitry configured to compensate for the potentially inaccurate outputs of the MVM operations using a dummy column of memory cells, as a reference column of memory cells, to generate the time varying reference voltage V_{Dummy}. The example circuitry shown in FIG. 6 includes a memory crossbar array 602, ROSCs 604 and ADCs 214.

The memory crossbar array 602 includes a plurality of groups of memory cell columns 606. Each column of memory cells in the groups of memory cell columns 606 is configured to generate a non-linear analog output voltage signal V_{MVM} for an activation vector. In addition, the memory crossbar array 602 also includes a plurality of dummy columns of memory cells (i.e., dummy columns) 608 interleaved between, and separate from, groups of memory cell columns 606. In the example shown in FIG. 6, each dummy column 608 is shared by a portion of a group of memory cell columns 606. That is, each dummy column 608 is shared by a portion of memory cell columns 606 (i.e., 4 memory columns of a group of memory cell columns 606 adjacent and to the left of the dummy column 608 and 4 memory columns of a group of memory cell columns 606 adjacent and to the right of the dummy column 608, totaling 8 shared memory cell columns). The number of memory cell columns 606 shared by each dummy column 608 in FIG. 6 is merely an example. Each dummy column 608 is configured to generate the time varying voltage values for a portion of the adjacent groups (i.e., to the left and right of the dummy column) of the plurality of columns of memory cells.

Each dummy column 608 also includes a column of memory cells (e.g., such as the memory cells shown in FIG. 2). The memory cells in each dummy column 608 are programmed and calibrated to generate a time varying voltage dummy ramp signal V_{Dummy} (as described above) such that when an ADC 214 combines the voltage dummy ramp signal V_{Dummy} with a non-linear analog output voltage signal V_{MVM} (generated by a memory cell column 606), V_{Dummy} is used as a reference to linearize the non-linear output voltage signal V_{MVM} and convert the linearized output voltage signal into a linear digital output.

Each dummy column 608 is shared by a plurality of the ROSCs 504 and a plurality of the ADCs 214. The number of ROSCs 504 and ADCs 214 shared by each dummy column 608 in FIG. 6 is merely an example. Features of the present disclosure can be implemented using any number of ROSCs 504 and ADCs 214 shared by each dummy column 608. A dummy column 608 can be shared by multiple memory cell columns 606 to provide the same reference voltage to each of the memory cell columns 606 sharing the same dummy column 608. Similarly, an ROSC 604 can be implemented to each column sharing the same reference voltage signal.

The dummy voltage V_{Dummy} is, for example, implemented in two phases of the conversion by the ADCs 214. During a sensing stage (e.g., MVM read phase), input digital bits that are translated into voltage pulses interact with weights stored as conductance to produce an MVM output in the voltage domain. Dedicated columns in the crossbar storing positive and negative weights generate respective positive V_{MVM} values and negative V_{MVM} values. The difference in the change in the V_{MVM} values is equal to the difference between the positive V_{MVM} values and the negative V_{MVM} values. That is, during the analog MVM operation, BLs are activated and ΔV_{MVM} is developed and sampled for digitization. Both positive ΔV_{MVM} outputs and negative outputs ΔV_{MVM} outputs are sampled, and the pair is digitalized using a differential ADC.

During the conversion phase, a dummy column storing conductance values, corresponding to the conductance values mapped to the memory cells of the columns generating the V_{MVM} value, is read out with each input activation to generate the time varying signal V_{Dummy}. During this period, a VTC based ADC unit converts ΔV_{MVM} using V_{Dummy} signal into time domain TMVM for further conversion. This VTC block includes a voltage-crossing detector (VCD) to determine the time it takes the time varying signal V_{Dummy} to cross the two differential signals to positive ΔV_{MVM} outputs and negative outputs ΔV_{MVM} outputs, which creates a time duration of value T_{MVM} proportional to the accurate MVM output. Because the amount of discharge depends on the effective conductance of the column, the time the replicated read cycle takes to reach a certain voltage is proportional to the column conductance corresponding to the given sampled voltage.

ΔV_{Dummy} is developed on dBL and the VCD detects the voltage crossings of the dBL with the sampled ΔV_{MVM} values on BLP and BLN, respectively. Since there are positive ΔV_{MVM} outputs and negative outputs ΔV_{MVM} outputs, two time stamps are captured. The time of the crossing ΔT_{MVM} is sent to the TDC. In the TDC, a ROSC running at a predetermined frequency is sampled between in the two time stamps. A number of pulse counts are counted using a ripple carry counter. Decoding of the states of the ROSC at the two time stamps is done using a thermometer code detector. The sign is determined using a sign comparator.

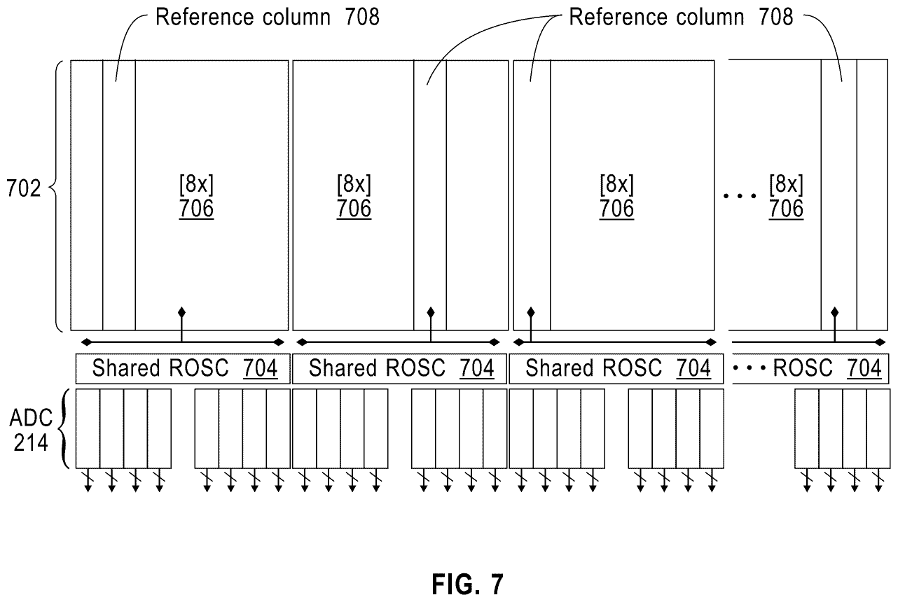

In another embodiment, the compensation for the potentially inaccurate outputs of the MVM operations is implemented by using one of the existing memory cell columns as the reference column of memory cells. For example, FIG. 7 illustrates example circuitry configured to compensate for the potentially inaccurate outputs of the MVM operations using existing memory cell columns as reference columns according to this embodiment. The example circuitry shown in FIG. 7 includes a memory crossbar array7602, ROSCs 704 and ADCs 214.

The memory crossbar array 702 includes a plurality of columns of memory cells (i.e., memory cell columns) 706 each of which are used to generate a non-linear analog output voltage signal V_{MVM} as described above. In addition, one of the existing memory cell columns 706 in a group of 8 memory cell columns 706 is used as reference column of memory cells (i.e., reference columns) 708. Features of the present disclosure can be implemented, however, by an existing memory cell columns 706 in a group of any number of memory cell columns 706. In an example, the memory cell column 706 in in the group of memory cell columns 706 that is used as the reference column 708 is the column which includes the maximum conductance of the group of memory cell columns 706.

Similar to the dummy column 608 described above with regard to FIG. 6, the memory cells in each reference column 708 are programmed and calibrated to generate a time varying voltage dummy ramp signal V_{Dummy} (as described above) such that when an ADC 214 combines the voltage dummy ramp signal V_{Dummy} with a non-linear analog output voltage signal V_{MVM} (generated by a memory cell column 706), V_{Dummy} is used as a reference to linearize the non-linear output voltage signal V_{MVM} and convert the linearized output voltage signal into a linear digital output.

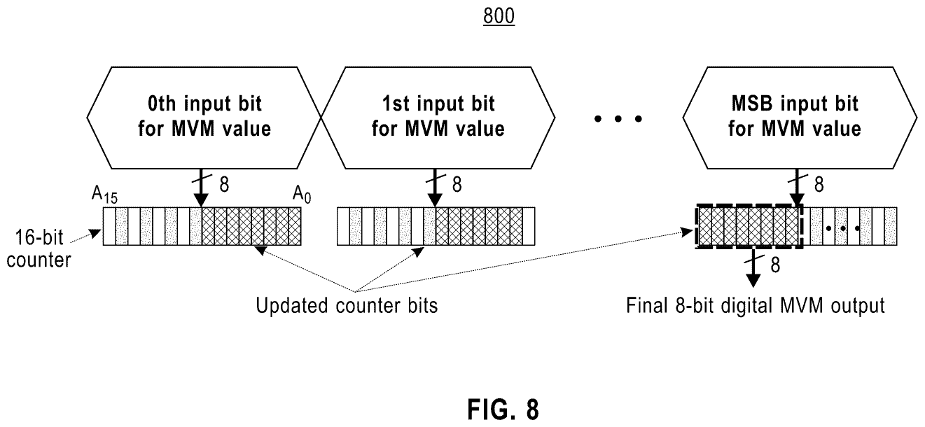

FIG. 8 is a diagram illustrating analog to digital conversion in each cycle of a bit-serial input encoding and accumulation of partial results on a counter, according to an embodiment of the present disclosure. As described above, each V_{MVM} input is multi-bit value, with each bit having a corresponding significance. In the embodiment shown in FIG. 8, for each multi-bit V_{MVM} value inputted to the memory crossbar array 208, the analog non-linear output voltage value V_{MVM} is converted in each clock cycle of a bit-serial input encoding and partial results are accumulated on a counter, while accounting for the varying input bit significance.

For example, as shown in FIG. 8, in a bit-serial mode (i.e., bits are inputted serially one-bit at a time), 1-bit is provided via a BL (e.g., wires 213 in FIG. 2) to the memory crossbar array in each clock cycle, (e.g., from the least significant bit (LSB) to the most significant bit (MSB). In the example shown in FIG. 8, in each cycle, an 8-bit output is produced and is collected in an increment counter (e.g. ADC counters 216 in FIG. 2), assuming the size of the counter is configured for 16 bits as shown in the example in FIG. 8.

The significance of the input bits is typically implemented by shifting the selected 8-bits to be incremented. The selected bits for incrementing are shifted, from the LSB to the MSB, by one (implying a scaling by a factor of x2). For example, for the LSB, bits A7-A0 are incremented; for the LSB+1, bits A8-A1 are incremented; and so on. The last bit (e.g., bit A15 is generally maintained in case of an overflow). The number of bits for further processing is generally much less than 16-bits (e.g., typically, in the range of 8-bits for AI applications which in this case, the most significant 8-bits of the counter (e.g., bits A15-A8) are propagated further and (A7-A0) are discarded).

As described above, input bits are inputted in a bit-serial fashion (one-bit at a time). The voltage-sensing mechanism samples V_{MVM(i)} at the end of each activation cycle. The nonlinear V_{MVM} relation with the accurate MVM value is translated into a linear time relation using a compensating dummy ramp. This dummy ramp is generated to capture and match the non-linearity of V_{MVM}. This includes a tunable resistive discharge path to a capacitive node whose voltage value is continuously compared with the sampled V_{MVM}. The time T_{MVM} is captured from the starting of the ramp to the voltage crossing of this ramp and the sampled V_{MVM} and this time duration is linear to the accurate MVM value.

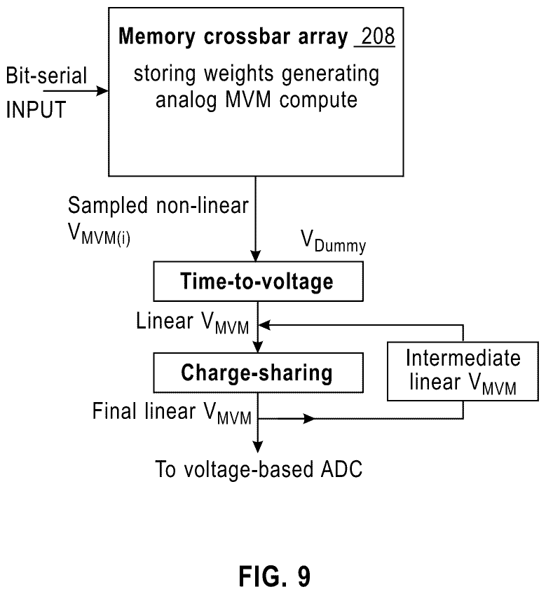

FIG. 9 is a diagram illustrating a multi-ramp scheme for processing the analog voltage values before the analog voltage values are converted into digital form according to an embodiment.

As shown in FIG. 9, in the multi-ramp scheme, the ramp (i.e., V_{Dummy}) is used in each activation cycle to convert the sampled non-linear voltage V_{MVM(i)}to the linear related time T_{MVM} (as shown in FIG. 4) and then to time-to-voltage convert which is then converted into an intermediate linear V_{MVM} for further processing (e.g., charge sharing before converting the final linear voltage (final linear V_{MVM}) into digital form. In this embodiment, V_{MVM} is converted one-time after the input cycles of a bit-serial input encoding, while accounting for varying input bit significance. In bit-serial mode, 1-bit is provided to the crossbar in each cycle (e.g., from LSB to MSB). In each of these cycles, a change in analog ΔT_{MVM} is obtained (linearly proportional to MVM from a non-linear voltage). However, ΔT_{MVM} is not converted to digital bits in each cycle. Rather, ΔT_{MVM} is be converted into a linear proportional voltage and then stored in sample-hold capacitors. The obtained ΔV_{MVM} is reduced to half of its value using charge-sharing with half of its value discarded using an equal-sized capacitor (implying a scaling by a factor of x½each time). This ΔV_{MVM}/2 is then combined with the succeeding voltage ΔV_{MVM}. After the input bit cycles are completed for a vector value, the obtained aggregated stored values are converted into digital using any voltage-based ADC (e.g., VTC-based ADC using ROSC) for digitization.

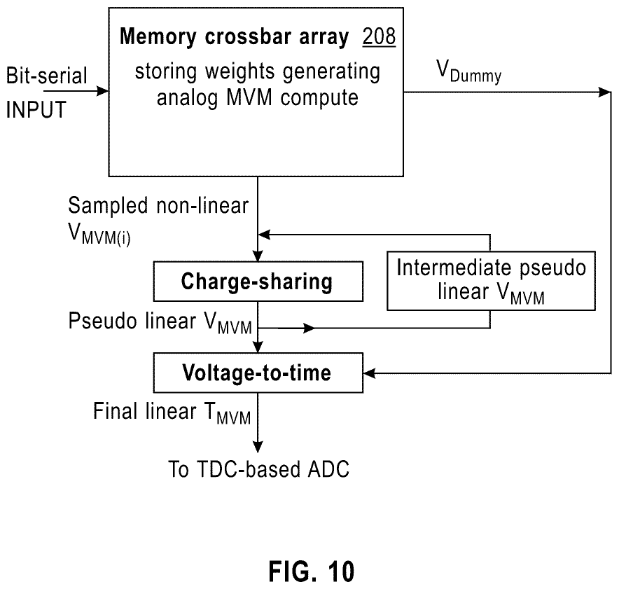

FIG. 10 is a diagram illustrating a single-ramp scheme for processing the analog voltage values before the analog voltage values are converted into digital form according to an embodiment of the present disclosure.

In this embodiment, the dummy ramp is used once to convert non-linear V_{MVM} to linear time T_{MVM}, which can be directly converted into digital form. The time-step (per accurate MVM count) and the dynamic range of the dummy ramp can be tuned by tuning the conductance of the resistive discharge path. To accommodate for multi-bit inputs and associated input bit significance, charge-sharing (as previously described) is used to combine intermediate voltage outputs to obtain a final voltage V_{MVM} output. Final voltage (linear V_{MVM}) as an output of multi-bit inputs can be provided as an input to any voltage-based ADC (e.g., VTC-based ADC using ROSC) for digitization.

In bit-serial mode, 1-bit is provided to the crossbar in each cycle (e.g., from LSB to MSB). In each of these cycles, ΔV_{MVM} obtained on the BL is pseudo-linear (i.e., pseudo-linear ΔV_{MVM} Because the voltage drop is small compared to the full-dynamic range of the BL voltage, the ΔV_{MVM} obtained in each cycle can be treated as a linear relation. These ΔV_{MVM} can be stored in sample-hold capacitors. and then, after the input bit cycles are completed for a vector value, the aggregated stored ΔV_{MVM} values are converted to digital using any voltage-based ADC (e.g., VTC-based ADC using ROSC) for digitization.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A computing device comprising:
a memory crossbar array comprising a plurality of memory cells each configured to store a value of a matrix to a conductance;
control logic circuitry configured to execute, via the plurality of memory cells, analog in-memory computing for matrix vector multiplication by controlling the plurality of memory cells to:
generate non-linear output values from the stored values of the matrix and analog input values of a vector; and
generate, time varying voltage values; and
a plurality of analog to digital converters configured to use the time varying voltage values to linearize the non-linear output values into analog linear output values and convert the analog linear output values to digital linear output values.

2. The computing device of claim 1, wherein the memory crossbar array comprises
a plurality of columns of memory cells, each column of memory cells configured to generate a non-linear output value from the stored values of the matrix and the analog input values of the vector; and
a dummy column of memory cells, separate from and adjacent to groups of the plurality of columns of memory cells, the dummy column configured to generate the time varying voltage values for a portion of the groups of the plurality of columns of memory cells adjacent to the dummy column.

3. The computing device of claim 1, wherein the memory crossbar array comprises;
a plurality of columns of memory cells, each column of memory cells configured to generate a non-linear output value from the stored values of the matrix and the analog input values of the vector, and
wherein a column of memory cells, of the plurality of columns of memory cells, is configured to generate the time varying voltage values for the plurality of columns of memory cells.

4. The computing device of claim 3, wherein the column of memory cells is a column of memory cells which includes a maximum conductance of the plurality of columns of memory cells.

5. The computing device of claim 1, wherein the control logic circuitry is configured to control the plurality of analog to digital converters to use the time varying voltage values to linearize the non-linear output values into analog linear output values and convert the analog linear output values to digital linear output values.

6. The computing device of claim 1, wherein the analog to digital converters comprise additional control logic circuitry configured to use the time varying voltage values to linearize the non-linear output values into analog linear output values and convert the analog linear output values to digital linear output values.

7. The computing device of claim 1, wherein the non-linear output values are non-linear voltage values.

8. The computing device of claim 1, wherein the non-linear output values are non-linear current values.

9. The computing device of claim 1, wherein a time varying voltage value is used in each of a plurality of input activation cycles of an analog non-linear output value to convert the analog non-linear output value to an intermediate linear output value and combine each intermediate linear output value to convert the analog non-linear output value to a digital linear output value.

10. The computing device of claim 1, wherein a single time varying voltage value is used for a plurality of input activation cycles of an analog non-linear output value to convert the analog non-linear output value to a digital linear output value.

11. A computer-implemented method comprising:
mapping values of a matrix to conductance values of a memory crossbar array;
inputting, to memory cells of the memory crossbar array, analog voltage values of an activation vector;
generating non-linear output values from the analog voltage values and the mapped conductance values;
generating, via the memory cells of the memory crossbar array, time varying voltage values; and
using the time varying voltage values to linearize the analog non-linear output values into analog linear output value and converting the analog linear output values to digital linear output values.

12. The computer-implemented method of claim 11, further comprising generating the time varying voltage values via a dummy column of memory cells, which is separate from columns of memory cells used to generate the non-linear output values.

13. The computer-implemented method of claim 11, further comprising generating the time varying voltage values via a reference column of memory cells which is part of a group of the memory cells used to generate the non-linear output values.

14. The computer-implemented method of claim 11, wherein the non-linear output values are non-linear voltage values.

15. The computer-implemented method of claim 11, wherein the non-linear output values are non-linear current values.

16. The computer-implemented method of claim 11, wherein bits corresponding to the analog voltage values of the activation vector are input serially to the memory cells in each clock cycle, the method further comprising:
converting, in each clock cycle, the analog non-linear output voltage value; and
accumulating, for each clock cycle via a counter, a partial value of the analog non-linear output voltage value while accounting for a significance of a corresponding bit of analog non-linear output voltage value.

17. The computer-implemented method of claim 11, further comprising using a time varying voltage value in each of a plurality of input activation cycles of an analog non-linear output value to convert the analog non-linear output value to an intermediate linear output value and combining each intermediate linear output value to convert the analog non-linear output value to a digital linear output value.

18. The computer-implemented method of claim 11, further comprising using a single time varying voltage value for a plurality of input activation cycles of an analog non-linear output value to convert the analog non-linear output value to a digital linear output value.

19. A computer program product comprising:
one or more computer-readable storage media; and
program instructions stored on the one or more computer-readable storage media to perform operations comprising:
mapping values of a matrix to conductance values of a memory crossbar array;
inputting, to the memory cells of the memory crossbar array, analog voltage values of an activation vector;
generating non-linear output values from the analog voltage values and the mapped conductance values;
generating, via the memory cells of the memory crossbar array, time varying voltage values; and
using the time varying voltage values to linearize the analog non-linear output values into analog linear output value and converting the analog linear output values to digital linear output values.

20. The computer program product of claim 19, wherein the operations further comprise generating the time varying voltage values via a dummy column of memory cells, which is separate from columns of memory cells used to generate the non-linear output values.

21. The computer program product of claim 19, wherein the operations further comprise generating the time varying voltage values via a reference column of memory cells which is part of a group of the memory cells used to generate the non-linear output values.

22. The computer program product of claim 19, wherein the non-linear output values are non-linear voltage values.

23. The computer program product of claim 19, wherein the non-linear output values are non-linear current values.

24. A computing device comprising:
a memory crossbar array comprising a plurality of columns of memory cells, each memory cell configured to store a value of a matrix to a conductance, the plurality of columns of memory cells comprising:
groups of columns of memory cells, each column of memory cells in a group of memory cells configured to generate a non-linear output value from stored values of the matrix and analog input values of a vector; and
dummy columns of memory cells, interleaved between and separate from the groups of columns of memory cells, each dummy column configured to generate a time varying voltage value for a portion of the groups of columns of memory cells adjacent to a corresponding dummy column;
control logic circuitry configured to execute, via the plurality of columns of memory cells, analog in-memory computing for matrix vector multiplication by controlling each column of memory cells to:
generate the non-linear output value from the stored values of the matrix and the analog input values of the vector; and
generate, the time varying voltage value for the portion of the groups of columns of memory cells adjacent to the corresponding dummy column; and
a plurality of analog to digital converters configured to use the time varying voltage values to linearize the non-linear output values into analog linear output values and convert the analog linear output values to digital linear output values.

25. A method comprising:
configuring a memory crossbar array, comprising a plurality of columns of memory cells, to store a value of a matrix to a conductance in each memory cell;
for the plurality of columns of memory cells, configuring each column of memory cells in a group of memory cells to generate a non-linear output value from the stored values of the matrix and analog input values of a vector;
configuring each of a plurality of dummy columns of memory cells, interleaved between and separate from the groups of columns of memory cells, to generate a time varying voltage value for a portion of the groups of columns of memory cells adjacent to a corresponding dummy column;
executing, via the plurality of columns of memory cells, analog in-memory computing for matrix vector multiplication by controlling:
each column of memory cells to generate the non-linear output value from the stored values of the matrix and the analog input values of the vector; and
each dummy column to generate, the time varying voltage value for the portion of the groups of columns of memory cells adjacent to the corresponding dummy column; and
using the time varying voltage values to linearize the analog non-linear output values into analog linear output values and convert the analog linear output values to digital linear output values.
